(19) United States
(12) Patent Application Publication
(10) Pub. No.: US 2025/0331148 A1
(43) Pub. Date: Oct. 23, 2025

(54) MEMORY CELLS WITH SEMICONDUCTOR LAYERS OF DIFFERENT DOPING LEVELS

(71) Applicant: Intel Corporation, Santa Clara, CA (US)

(72) Inventors: Abhishek A. Sharma, Portland, OR (US); Anand S. Murthy, Portland, OR (US); Tahir Ghani, Portland, OR (US); Wilfred Gomes, Portland, OR (US)

(73) Assignee: Intel Corporation, Santa Clara, CA (US)

(21) Appl. No.: 18/641,646

(22) Filed: Apr. 22, 2024

(51) Int. Cl. H10B 10/00

(52) U.S. Cl. CPC H10B 10/125

(57) ABSTRACT

Disclosed herein are memory cells with semiconductor layers of different doping levels, and related devices and techniques. In some embodiments, a memory cell may include a first semiconductor layer, a second semiconductor layer on the first semiconductor layer, a third semiconductor layer on the second semiconductor layer, a fourth semiconductor layer on the third semiconductor layer, a fifth semiconductor layer on the fourth semiconductor layer, and a sixth semiconductor layer on the fifth semiconductor layer, wherein dopant concentrations of the first semiconductor layer, the fourth semiconductor layer, and the sixth semiconductor layer are higher than dopant concentrations of the second semiconductor layer, the third semiconductor layer, and the fifth semiconductor layer.

### BACKGROUND

A non-volatile random-access memory (NVRAM) device is a memory device that retains its data in the absence of supplied power. Flash memory is an example of an existing non-volatile memory technology. A volatile random-access memory (VRAM) device is a memory device that loses its data when power is removed or turned off. Static random-access memory (SRAM) is an example of an existing volatile memory technology. In certain applications, volatile memory may be preferred over non-volatile memory due to advantages in terms of speed, power efficiency, simplicity, latency, and endurance.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a perspective view of a portion of a memory array including memory cells with semiconductor layers of different doping levels, in accordance with various embodiments.

FIG. 1B is a schematic illustration of a memory cell of the memory array of FIG. 1A, in accordance with various embodiments.

FIG. 1C is an electric circuit representation of a memory cell of the memory array of FIG. 1A, in accordance with various embodiments.

FIG. 2 is a schematic illustration of a memory device including memory cells with semiconductor layers of different doping levels, in accordance with various embodiments.

FIG. 3 is a flow diagram of an illustrative method of manufacturing a memory cell with semiconductor layers of different doping levels, in accordance with various embodiments.

FIG. 4 illustrates top views of a wafer and dies that may include one or more integrated circuit (IC) structures with memory cells with semiconductor layers of different doping levels, in accordance with various embodiments.

FIG. 5 is a side, cross-sectional view of an IC device that may include one or more IC structures with memory cells with semiconductor layers of different doping levels, in accordance with various embodiments.

FIG. 6 is a side, cross-sectional view of an IC package that may include one or more IC structures with memory cells with semiconductor layers of different doping levels, in accordance with various embodiments.

FIG. 7 illustrates a cross-sectional side view of an IC device assembly that may include one or more IC structures with memory cells with semiconductor layers of different doping levels, in accordance with various embodiments.

FIG. 8 is a block diagram of an example computing device that may include one or more IC structures with memory cells with semiconductor layers of different doping levels, in accordance with various embodiments.

FIG. 9 is a block diagram of an example processing device that may include one or more IC structures with memory cells with semiconductor layers of different doping levels, in accordance with various embodiments.

### DETAILED DESCRIPTION

Disclosed herein are memory cells with semiconductor layers of different doping levels, and related devices and techniques. In some embodiments, a memory cell may include a first semiconductor layer, a second semiconductor layer on the first semiconductor layer, a third semiconductor layer on the second semiconductor layer, a fourth semiconductor layer on the third semiconductor layer, a fifth semiconductor layer on the fourth semiconductor layer, and a sixth semiconductor layer on the fifth semiconductor layer, wherein dopant concentrations of the first semiconductor layer, the fourth semiconductor layer, and the sixth semiconductor layer are higher than dopant concentrations of the second semiconductor layer, the third semiconductor layer, and the fifth semiconductor layer.

In the following detailed description, various aspects of the illustrative implementations may be described using terms commonly employed by those skilled in the art to convey the substance of their work to others skilled in the art. For example, the term “connected” means a direct electrical connection between the things that are connected (e.g., with the things being in electrically conductive and/or physical contact with), without any intermediary devices, while the term “coupled” means either a direct electrical connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulator material” may refer to solid materials (and/or liquid materials that solidify after processing as described herein) that are substantially electrically non-conducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting/conductive” can also mean “optically conducting/conductive.”

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

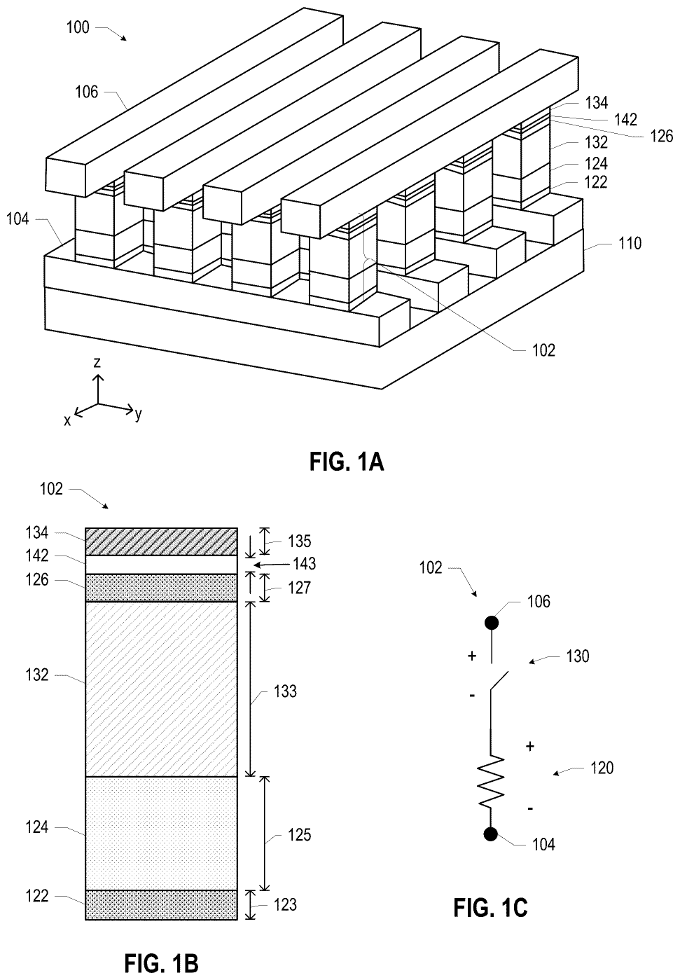

Any of the features discussed with reference to any of accompanying drawings herein may be combined with any other features to form IC structures with memory cells with semiconductor layers of different doping levels, as appropriate. A number of elements of the drawings are shared with others of the drawings; for ease of discussion, a description of these elements is not repeated, and these elements may take the form of any of the embodiments disclosed herein. If multiple instances of certain elements are illustrated, then, in some cases, to not clutter the drawings only some of these elements may be labeled with a reference sign and other ones of these elements are not labeled (e.g., although FIG. 1A illustrates multiple conductive lines 104 and 106, only one of each is labeled with a reference sign). However, in other cases, for ease of explanation, different instances of a given element in a single drawing may be referred to with numbers 1, 2, and so on, after a dash.

The drawings are not necessarily to scale. In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with memory cells with semiconductor layers of different doping levels as described herein.

Various IC structures with memory cells with semiconductor layers of different doping levels as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

FIG. 1A is a perspective view of a portion of a memory array 100 including memory cells 102 with semiconductor layers of different doping levels, in accordance with various embodiments. The memory array 100 may be a cross-point array including memory cells 102 located at the intersections of conductive lines 104 and conductive lines 106. In some embodiments, the conductive lines 104 may be bit lines and the conductive lines 106 may be word lines, or vice versa, even though the descriptions provided herein are applicable to any other scenarios where the conductive lines 104 and the conductive lines 106 are any memory control lines. In the embodiment illustrated in FIG. 1A, the conductive lines 104 may be parallel to each other and may be arranged perpendicularly to the conductive lines 106 (which themselves may be parallel to each other), but any other suitable arrangement may be used. The conductive lines 104 and/or the conductive lines 106 may be formed of any suitable conductive material, such as a metal (e.g., tungsten, copper, titanium, or aluminum). In some embodiments, the memory array 100 depicted in FIG. 1A may be a portion (e.g., a level) of a three-dimensional array in which other memory arrays like the memory array 100 of FIG. 1A are located at different levels (e.g., above or below the memory array 100).

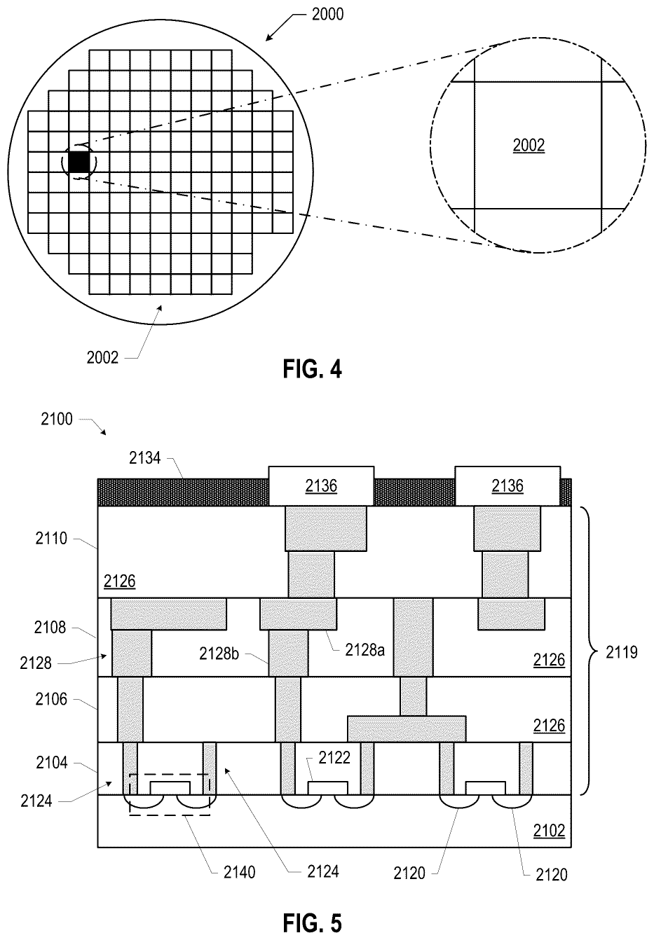

As shown in FIG. 1A, the memory cells 102 may be provided over a substrate 110. The substrate 110 may be any suitable support over which the memory array 100 may be provided. For example, the substrate 110 may be a die, a wafer, a chip, or any other suitable support structure. The substrate 110 may, e.g., be the wafer 2000 of FIG. 4, discussed below, and may be, or be included in, a die, e.g., the singulated die 2002 of FIG. 4, discussed below. The substrate 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the substrate 110 may be a printed circuit board (PCB) substrate. Although a few examples of materials from which the substrate may be formed are described here, any material that may serve as a foundation upon which a semiconductor device implementing any of the memory cells with semiconductor layers of different doping levels as described herein may be built falls within the spirit and scope of the present disclosure.

Although not specifically shown in FIG. 1A, additional layers may be present between the substrate 110 and the memory array 100, e.g., between the substrate 110 and the conductive lines 104. Such additional layers may include insulator layers, and may include any combination of other components (e.g., ICs) provided over the substrate 110. For example, in some embodiments, one or more additional layers between the substrate 110 and the memory array 100 may include various logic layers, circuits, and devices (e.g., logic transistors) to drive and control a logic IC.

Each memory cell 102 may include semiconductor layers of different doping levels. In particular, a memory cell 102 may include semiconductor layers 122, 124, and 126 having a first conductivity type, and further include semiconductor layers 132 and 134 having a second conductivity type opposite to the first conductivity type. As used herein, a “conductivity type” refers to the P-type or N-type conductivity of a material. For example, the semiconductor layers 122, 124, and 126 may be N-type semiconductor layers, while the semiconductor layers 132 and 134 may be P-type semiconductor layers; for the ease of discussion, this terminology may be used herein to refer to the semiconductor layers 122, 124, and 126 and the semiconductor layers 132 and 134. However, descriptions provided herein are equally applicable to the semiconductor layers 122, 124, and 126 being P-type semiconductor layers and the semiconductor layers 132 and 134 being N-type semiconductor layers. Each memory cell 102 may further include a buffer layer 142.

FIG. 1B is a schematic illustration of a memory cell 102 of the memory array of FIG. 1A, in accordance with various embodiments. As shown in FIG. 1A and FIG. 1B, various layers of a memory cell 102 may be arranged as follows: the N-type semiconductor layer 124 may be between the N-type semiconductor layer 122 and the P-type semiconductor layer 132, the P-type semiconductor layer 132 may be between the N-type semiconductor layer 124 and the N-type semiconductor layer 126, the N-type semiconductor layer 126 may be between the P-type semiconductor layer 132 and the buffer layer 142, and the buffer layer 142 may be between the N-type semiconductor layer 126 and the P-type semiconductor layer 134. While the present drawings illustrate the N-type semiconductor layer 122 to be at the bottom and the P-type semiconductor layer 134 to be at the top of the stack of the semiconductor layers of the memory cells 102, in other embodiments, the order of the semiconductor layers of the memory cells 102 may be reversed, as long as the relative orientations of semiconductor layers arranged between two other semiconductor layers remains as described above (i.e., as long as the N-type semiconductor layer 124 is between the N-type semiconductor layer 122 and the P-type semiconductor layer 132, the P-type semiconductor layer 132 is between the N-type semiconductor layer 124 and the N-type semiconductor layer 126, the N-type semiconductor layer 126 is between the P-type semiconductor layer 132 and the buffer layer 142, and the buffer layer 142 is between the N-type semiconductor layer 126 and the P-type semiconductor layer 134). Adjacent layers of a memory cell 102 may be in direct physical contact with one another, e.g., the N-type semiconductor layer 124 may be in direct physical contact with the N-type semiconductor layer 122, the P-type semiconductor layer 132 may be in direct physical contact with the N-type semiconductor layer 124, the N-type semiconductor layer 126 may be in direct physical contact with the P-type semiconductor layer 132, the buffer layer 142 may be in direct physical contact with the N-type semiconductor layer 126, and the P-type semiconductor layer 134 may be in direct physical contact with the buffer layer 142.

As shown in FIG. 1B, the N-type semiconductor layer 122 may have a thickness 123, the N-type semiconductor layer 124 may have a thickness 125, the P-type semiconductor layer 132 may have a thickness 133, the N-type semiconductor layer 126 may have a thickness 127, the buffer layer 142 may have a thickness 143, and the P-type semiconductor layer 134 may have a thickness 135. Any of the thicknesses 123, 127, and 135 may be between about 3 nanometers and about 100 nanometers, e.g., between about 3 nanometers and about 10 nanometers, between about 3 nanometers and about 50 nanometers, or between about 5 nanometers and about 25 nanometers. The thickness 133 may be larger than thicknesses of all other layers of the memory cell 102 in order to ensure that the P-type semiconductor layer 132 may function as a storage element 120, as described below. For example, in some embodiments, the thickness 133 may be between about 2 times and about 100 times larger than any of the thicknesses 123, 127, or 135, e.g., between about 2 times and about 10 times larger, between about 2 times and about 50 times larger, or between about 50 times and about 100 times larger. The thickness 125 may be smaller than the thickness 133 but larger than any of the thicknesses 123, 127, or 135. Inventors of the present disclosure realized that thicknesses for various layers of the memory cells 102 may achieve an optimal balance between providing charge and limiting leakage in the memory cells 102. In particular, layers of the memory cells 102 that have higher dopant concentrations (e.g., the n-type semiconductor layers 122, the n-type semiconductor layers 126, and the p-type semiconductor layers 134) have smaller thicknesses which may be advantageous in terms of providing charge in the memory cells 102. On the other hand, layers of the memory cells 102 that have lower dopant concentrations (e.g., the p-type semiconductor layers 132, and the n-type semiconductor layers 124) have larger thicknesses which may be advantageous in terms of reducing or eliminating charge leakage in the memory cells 102. The thickness 143 may be smaller than any of the thicknesses 123, 127, or 135. For example, in some embodiments, the thickness 143 may be between about 30 percent of any of the thicknesses 123, 127, or 135, in order to prevent very high electric fields between the p-type semiconductor layers 134 and the n-type semiconductor layers 126.

The N-type semiconductor layer 122, the N-type semiconductor layer 126, and the P-type semiconductor layer 134 may have the highest dopant concentrations of all other layers of the memory cell 102 and, therefore, may be referred to as “highly-doped” layers. For example, in some embodiments, a dopant concentration of each of the N-type semiconductor layer 122, the N-type semiconductor layer 126, and the P-type semiconductor layer 134 may be at least about 10¹⁸ dopants per cubic centimeter, e.g., at least about 10¹⁹ dopants per cubic centimeter or at least about 1020 dopants per cubic centimeter. In various embodiments, dopant concentrations of any two or more of the N-type semiconductor layer 122, the N-type semiconductor layer 126, and the P-type semiconductor layer 134 may be substantially the same or different.

The N-type semiconductor layer 124 and the P-type semiconductor layer 132 may have dopant concentrations lower than the lowest dopant concentration of the N-type semiconductor layer 122, the N-type semiconductor layer 126, and the P-type semiconductor layer 134, but higher than a dopant concentration of the buffer layer 142 and, therefore, may be referred to as “lightly-doped” layers. For example, in some embodiments, a dopant concentration of each of the N-type semiconductor layer 124 and the P-type semiconductor layer 132 may be between about 10¹³ dopants per cubic centimeter and about 10¹⁸ dopants per cubic centimeter, e.g., between about 10¹⁴ dopants per cubic centimeter and about 10¹⁸ dopants per cubic centimeter or between about 10¹⁵ dopants per cubic centimeter and about 10¹⁸ dopants per cubic centimeter. In various embodiments, dopant concentrations of the N-type semiconductor layer 124 and the P-type semiconductor layer 132 may be substantially the same or different.

The buffer layer 142 may have the lowest dopant concentrations of all other layers of the memory cell 102 and, therefore, may be referred to as a “lightly-doped” or an “intrinsic” layer. For example, in some embodiments, a dopant concentration of the buffer layer 142 may be below about 10¹⁵ dopants per cubic centimeter, e.g., between about 10¹⁰ dopants per cubic centimeter and about 10¹⁵ dopants per cubic centimeter or between about 10¹⁰ dopants per cubic centimeter and about 10¹⁴ dopants per cubic centimeter or below about 10¹³ dopants per cubic centimeter. If the buffer layer 142 is a lightly-doped layer, then it may be either an N-type semiconductor layer or a P-type semiconductor layer.

The N-type semiconductor layers 122, 124, and 126, the P-type semiconductor layers 132 and 134, and the buffer layer 142 may include any suitable semiconductor materials, and each of these layers may include a combination of multiple semiconductor materials.

In some embodiments, any of the N-type semiconductor layers 122, 124, and 126, the P-type semiconductor layers 132 and 134, and the buffer layer 142 may include a substantially monocrystalline semiconductor, such as silicon (Si) or germanium (Ge). In some embodiments, any of the N-type semiconductor layers 122, 124, and 126, the P-type semiconductor layers 132 and 134, and the buffer layer 142 may include a compound semiconductor with a first sub-lattice of at least one element from group Ill of the periodic table (e.g., Al, Ga, In), and a second sub-lattice of at least one element of group V of the periodic table (e.g., P, As, Sb). In some embodiments, any of the N-type semiconductor layers 122, 124, and 126, the P-type semiconductor layers 132 and 134, and the buffer layer 142 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, any of the N-type semiconductor layers 122, 124, and 126, the P-type semiconductor layers 132 and 134, and the buffer layer 142 may include a combination of semiconductor materials. In some embodiments, any of the N-type semiconductor layers 122, 124, and 126, and the P-type semiconductor layers 132 and 134 may include a III-V material having a relatively high electron mobility, such as, but not limited to InGaAs, InP, InSb, and InAs. For some such embodiments, the semiconductor material may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments, the any of the N-type semiconductor layers 122, 124, and 126, and the P-type semiconductor layers 132 and 134 may advantageously be a group IV material having a high hole mobility, such as, but not limited to Ge or a Ge-rich SiGe alloy. For some such embodiments, the semiconductor material may have a Ge content between 0.6 and 0.9, and advantageously may be at least 0.7. In some embodiments, any of the N-type semiconductor layers 122, 124, and 126, the P-type semiconductor layers 132 and 134, and the buffer layer 142 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, any of the N-type semiconductor layers 122, 124, and 126, the P-type semiconductor layers 132 and 134, and the buffer layer 142 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

In some embodiments, any of the N-type semiconductor layers 122, 124, and 126, the P-type semiconductor layers 132 and 134, and the buffer layer 142 may include a thin-film semiconductor material. A thin-film semiconductor material may be deposited over a support (e.g., a substrate 110 as described above) that may be a non-conducting support. Some such materials may be deposited at relatively low temperatures, which allows depositing them within the thermal budgets to avoid damaging other components such as the logic devices of an IC structure. In other embodiments, any of the N-type semiconductor layers 122, 124, and 126, the P-type semiconductor layers 132 and 134, and the buffer layer 142 may include one or more semiconductor materials that are epitaxially grown in what typically involves relatively high-temperature processing. Whether they are implemented as thin-film semiconductor materials or as epitaxially grown semiconductor materials, any of the N-type semiconductor layers 122, 124, and 126, the P-type semiconductor layers 132 and 134, and the buffer layer 142 may include any of the semiconductor materials described above, including oxide semiconductor materials. Any of the N-type semiconductor layers 122, 124, and 126, the P-type semiconductor layers 132 and 134, and the buffer layer 142 that is implemented as thin-film semiconductor materials may be a polycrystalline, polymorphous, or amorphous semiconductor, or any combination thereof. Any of the N-type semiconductor layers 122, 124, and 126, the P-type semiconductor layers 132 and 134, and the buffer layer 142 that is implemented as an epitaxially grown semiconductor material may be a highly crystalline (e.g., monocrystalline, or single-crystalline) material. Therefore, whether the semiconductor material of any of the N-type semiconductor layers 122, 124, and 126, the P-type semiconductor layers 132 and 134, and the buffer layer 142 is a thin-film semiconductor material deposited at relatively low temperatures or epitaxially grown can be identified by inspecting grain size of the material. An average grain size of a semiconductor material of any of the N-type semiconductor layers 122, 124, and 126, the P-type semiconductor layers 132 and 134, and the buffer layer 142 being between about 0.5 and 1 millimeters (in which case the material may be polycrystalline) or smaller than about 0.5 millimeter (in which case the material may be polymorphous or amorphous) may be indicative of the semiconductor material having been deposited using a low-temperature process. On the other hand, an average grain size of a semiconductor material of any of the N-type semiconductor layers 122, 124, and 126, the P-type semiconductor layers 132 and 134, and the buffer layer 142 being equal to or greater than about 1 millimeter (in which case the material may be a single-crystal material) may be indicative of the semiconductor material having been epitaxially grown and included in the IC structure either by monolithic integration or by layer transfer. Realizing memory cells 102 as memory cells with semiconductor layers (e.g., the N-type semiconductor layers 122, 124, and 126, the P-type semiconductor layers 132 and 134, and the buffer layer 142) of different doping levels, as opposed to special memory materials, e.g., those used in conventional SRAM, may result in improved performance, simpler and/or less expensive manufacturing, and/or decreased power consumption relative to conventional memory cells.

FIG. 1C is an electric circuit representation of a memory cell 102 of the memory array of FIG. 1A, in accordance with various embodiments. As shown in FIG. 1C, the memory cell 102 may be represented as a storage element 120 coupled in series with an associated selector device 130. The P-type semiconductor layer 132 may be the storage element 120, while all of the other layers of the memory cell 102 (e.g., the N-type semiconductor layers 122 and 126, the P-type semiconductor layers 132 and 134, and the buffer layer 142) may act as the associated selector device 130. Generally, the storage element 120 may be programmed to a target data state (e.g., corresponding to a particular resistance state) by applying an electric field or energy (e.g., positive or negative voltage or current pulses) to a pair of the conductive lines 104 and 106 for a particular duration. The storage element 120 may be, for example, a resistive storage element that, during operation, switches between two different non-volatile states: a high resistance state (HRS) and a low resistance state (LRS). The state of a resistive storage element may be used to represent a data bit (e.g., a “1” for HRS and a “0” for LRS, or vice versa). A resistive storage element may have a voltage threshold beyond which the resistive storage element is in the LRS. Similarly, a resistive storage element may have a voltage threshold beyond which the resistive storage element is in the HRS.

The selector device 130 may be a two-terminal device that may act as a bipolar switch, controlling the flow of current through the storage element 120. As illustrated in FIG. 1C, when the selector device 130 is in a conductive state, the “switch” may be closed; when the selector device 130 is in a non-conductive state, the “switch” may be open. The state of the selector device 130 may change in response to the voltage applied across the selector device 130. In particular, as illustrated in FIG. 1C, the selector device 130 may be in a non-conductive state when the voltage across the selector device 130 is between the negative threshold voltage Von− and the positive threshold voltage Von+. When the voltage across the selector device 130 reaches and exceeds the positive threshold voltage Von+, the selector device 130 may conduct current of a positive polarity; similarly, when the voltage across the selector device reaches and drops below the negative threshold voltage Von−, the selector device 130 may conduct current of a negative polarity. The selector device 130 may thus act as a bipolar switch, controlling the flow of current in positive and negative directions in accordance with respective positive and negative thresholds. Further, the selector device 130 may be asymmetric in that the magnitude of the positive threshold voltage Von+ is different from the magnitude of the negative threshold voltage Von−. Selector devices used in conventional memory cells do not exhibit such asymmetry; instead, the negative and positive threshold voltages have the same magnitude. Such symmetric selectors, however, may not be well matched to storage elements 120 that themselves exhibit asymmetric behavior. The asymmetric selector devices 130 disclosed herein may advantageously match asymmetric storage elements 120, resulting in improved performance and decreased power consumption relative to conventional memory cells.

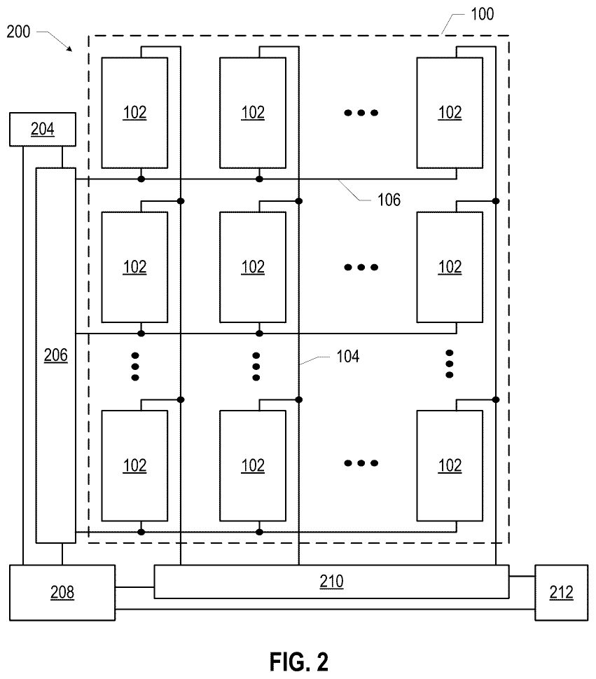

A memory array 100 including memory cells 102 with semiconductor layers of different doping levels may be controlled in any suitable manner. For example, FIG. 2 is a schematic illustration of a memory device 200 including a memory array 100 having memory cells 102 with the N-type semiconductor layers 122, 124, and 126, the P-type semiconductor layers 132 and 134, and the buffer layer 142, in accordance with various embodiments. The memory device 200 of FIG. 2 may be a bidirectional cross-point array in which each column is associated with a bit line (e.g., a conductive line 104) driven by column select circuitry 210. Each row may be associated with a word line (e.g., a conductive line 106) driven by row select circuitry 206. During operation, read/write control circuitry 208 may receive memory access requests (e.g., from one or more processing devices or communication chips of a computing device, such as the computing device 2400 discussed below), and may respond by generating an appropriate control signal (e.g., read, write 0, or write 1), as known in the art. The read/write control circuitry 208 may control the row select circuitry 206 and the column select circuitry 210 to select the desired memory cell(s) 102. Voltage supplies 204 and 212 may be controlled to provide the voltage(s) necessary to bias the memory array 100 to facilitate the requested action on one or more memory cells 102. Row select circuitry 206 and column select circuitry 210 may apply appropriate voltages across the memory array 100 to access the selected memory cells 102 (e.g., by providing appropriate voltages to the memory cells 102 to allow the desired selector devices 130 to conduct). Row select circuitry 206, column select circuitry 210, and read/write control circuitry 208 may be implemented using any devices and techniques known in the art.

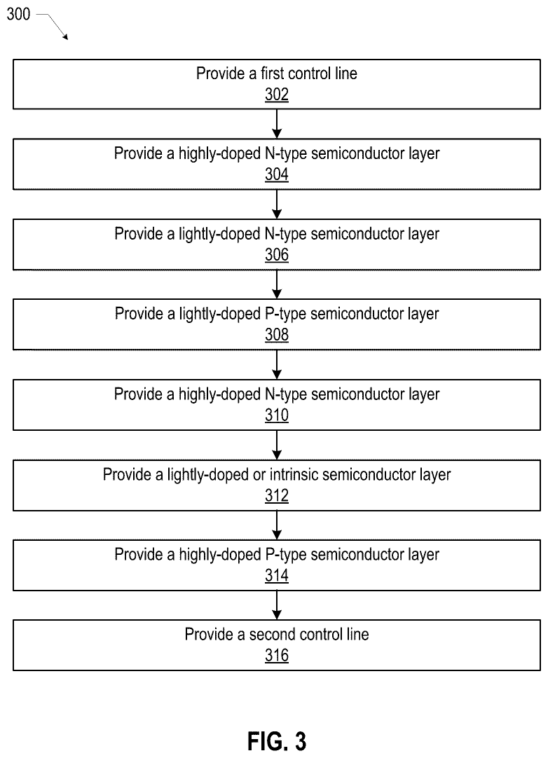

Any suitable techniques may be used to manufacture the memory cells 102 disclosed herein. FIG. 3 is a flow diagram of an illustrative method 300 of manufacturing a memory cell 102, in accordance with various embodiments. Although the operations discussed below with reference to the method 300 are illustrated in a particular order and depicted once each, these operations may be repeated or performed in a different order (e.g., in parallel), as suitable. Additionally, various operations may be omitted, as suitable. Various operations of the method 300 may be illustrated with reference to one or more of the embodiments discussed above, but the method 300 may be used to manufacture any suitable memory cells with semiconductor layers of different doping levels (including any suitable ones of the embodiments disclosed herein).

At 302, a first electrode in the form of a first conductive line may be formed (e.g., by physical vapor deposition (PVD), such as sputtering). For example, the first conductive line provided at 302 may take any of the forms of the conductive line 104 disclosed herein.

At 304, a highly-doped N-type semiconductor layer of the future memory cell 102 may be provided on the first conductive line 104 (e.g., by epitaxial deposition, low-temperature deposition, or layer transfer). The highly-doped N-type semiconductor layer provided at 304 may take any of the forms of the N-type semiconductor layer 122 disclosed herein.

At 306, a lightly-doped N-type semiconductor layer of the future memory cell 102 may be provided on the highly-doped N-type semiconductor layer provided at 304 (e.g., by epitaxial deposition, low-temperature deposition, or layer transfer). The lightly-doped N-type semiconductor layer provided at 306 may take any of the forms of the N-type semiconductor layer 124 disclosed herein.

At 308, a lightly-doped P-type semiconductor layer of the future memory cell 102 may be provided on the lightly-doped N-type semiconductor layer provided at 306 (e.g., by epitaxial deposition, low-temperature deposition, or layer transfer). The lightly-doped P-type semiconductor layer provided at 308 may take any of the forms of the P-type semiconductor layer 132 disclosed herein.

At 310, a highly-doped N-type semiconductor layer of the future memory cell 102 may be provided on the lightly-doped P-type semiconductor layer provided at 308 (e.g., by epitaxial deposition, low-temperature deposition, or layer transfer). The highly-doped N-type semiconductor layer provided at 310 may take any of the forms of the N-type semiconductor layer 126 disclosed herein.

At 312, a lightly-doped or intrinsic semiconductor layer of the future memory cell 102 may be provided on the highly-doped N-type semiconductor layer provided at 310 (e.g., by epitaxial deposition, low-temperature deposition, or layer transfer). The lightly-doped or intrinsic semiconductor layer provided at 312 may take any of the forms of the buffer layer 142 disclosed herein.

At 314, a highly-doped P-type semiconductor layer of the future memory cell 102 may be provided on the lightly-doped or intrinsic semiconductor layer provided at 312 (e.g., by epitaxial deposition, low-temperature deposition, or layer transfer). The highly-doped P-type semiconductor layer provided at 314 may take any of the forms of the P-type semiconductor layer 134 disclosed herein.

At 316, a second electrode in the form of a second conductive line may be formed on the highly-doped P-type semiconductor layer provided at 314 (e.g., by PVD, such as sputtering). For example, the second conductive line provided at 316 may take any of the forms of the conductive line 106 disclosed herein.

The IC structures with memory cells with semiconductor layers of different doping levels disclosed herein (e.g., any of the IC structures described with reference to FIGS. 1-3) may be included in any suitable electronic device. FIGS. 4-9 illustrate various examples of apparatuses that may include one or more IC structures with memory cells with semiconductor layers of different doping levels disclosed herein.

FIG. 4 illustrates top views of a wafer and dies that include one or more IC structures with memory cells with semiconductor layers of different doping levels in accordance with any of the embodiments disclosed herein. The wafer 2000 may be composed of semiconductor material and may include one or more dies 2002 having IC structures formed on a surface of the wafer 2000. Each of the dies 2002 may be a repeating unit of a semiconductor product that includes any suitable IC structure (e.g., any of the IC structures described with reference to FIGS. 1-3). After the fabrication of the semiconductor product is complete (e.g., after manufacture of one or more IC structures with one or more memory cells with semiconductor layers of different doping levels as described herein), the wafer 2000 may undergo a singulation process in which each of the dies 2002 is separated from one another to provide discrete “chips” of the semiconductor product. In particular, devices that include one or more IC structures with one or more memory cells with semiconductor layers of different doping levels as disclosed herein may take the form of the wafer 2000 (e.g., not singulated) or the form of the die 2002 (e.g., singulated). The die 2002 may include one or more memory cells with semiconductor layers of different doping levels, one or more transistors (e.g., some of the transistors 2140 of FIG. 5, discussed below) and/or supporting circuitry to route electrical signals to the memory cells with semiconductor layers of different doping levels, as well as any other IC components. In some embodiments, the wafer 2000 or the die 2002 may include a memory device (e.g., a memory device with memory cells with semiconductor layers of different doping levels), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2500 of FIG. 9) or other logic that is configured to store information in the memory devices or execute instructions stored in the memory array.

FIG. 5 is a side, cross-sectional view of an IC device 2100 that may include one or more IC structures with memory cells with semiconductor layers of different doping levels, in accordance with various embodiments. For example, memory cells 102 with semiconductor layers of different doping levels may be implemented in one or more device layers 2104 and/or in one or more interconnect layers 2106, 2108, and 2110 of the IC device 2100. In another example, one or more of the IC devices 2100 may be included in one or more dies 2002 of FIG. 4. The IC device 2100 may be formed on a substrate 2102 (e.g., the wafer 2000 of FIG. 4) and may be included in a die (e.g., the die 2002 of FIG. 4). The substrate 2102 may take on any forms of the substrate 110, described above.

The IC device 2100 may include one or more device layers 2104 disposed on the substrate 2102. The device layer 2104 may include features of one or more transistors 2140 (e.g., metal oxide semiconductor field-effect transistors (MOSFETs)) formed on the substrate 2102. The device layer 2104 may include, for example, one or more source and/or drain (S/D) regions 2120, a gate 2122 to control current flow in the transistors 2140 between the S/D regions 2120, and one or more S/D contacts 2124 to route electrical signals to/from the S/D regions 2120. The transistors 2140 may include additional features not depicted for the sake of clarity, such as device isolation regions, gate contacts, and the like. The transistors 2140 are not limited to the type and configuration depicted in FIG. 5 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 2140 may include a gate 2122 formed of at least two layers, a gate insulator and a gate electrode. The gate insulator may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate insulator include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate insulator to improve its quality when a high-k material is used.

The gate electrode may be formed on the gate insulator and may include at least one P-type work function metal or N-type work function metal, depending on whether the transistor 2140 is to be a P-type metal oxide semiconductor (PMOS) or an N-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 2140 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 2120 may be formed within the substrate 2102 adjacent to the gate 2122 of each transistor 2140. The S/D regions 2120 may be formed using an implantation/diffusion process or an etching/deposition process, for example. In the former process, dopants such as boron, aluminum, antimony, phosphorous, or arsenic may be ion-implanted into the substrate 2102 to form the S/D regions 2120. An annealing process that activates the dopants and causes them to diffuse farther into the substrate 2102 may follow the ion-implantation process. In the latter process, the substrate 2102 may first be etched to form recesses at the locations of the S/D regions 2120. An epitaxial deposition process may then be carried out to fill the recesses with material that is used to fabricate the S/D regions 2120. In some implementations, the S/D regions 2120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2120 may be formed using one or more alternate semiconductor materials such as germanium or a group III-V material or alloy. In further embodiments, one or more layers of metal and/or metal alloys may be used to form the S/D regions 2120.

Electrical signals, such as power and/or input/output (I/O) signals, may be routed to and/or from the devices (e.g., the transistors 2140) of the device layer 2104 through one or more interconnect layers disposed on the device layer 2104 (illustrated in FIG. 5 as interconnect layers 2106, 2108, and 2110). For example, electrically conductive features of the device layer 2104 (e.g., the gate 2122 and the S/D contacts 2124) may be electrically coupled with the interconnect structures 2128 of the interconnect layers 2106, 2108, and 2110. The one or more interconnect layers 2106, 2108, and 2110 may form a metallization stack (also referred to as an “ILD stack”) 2119 of the IC device 2100.

The interconnect structures 2128 may be arranged within the interconnect layers 2106, 2108, and 2110 to route electrical signals according to a wide variety of designs (in particular, the arrangement is not limited to the particular configuration of interconnect structures 2128 depicted in FIG. 5). Although a particular number of interconnect layers 2106, 2108, and 2110 is depicted in FIG. 5, embodiments of the present disclosure include IC devices having more or fewer interconnect layers than depicted.

In some embodiments, the interconnect structures 2128 may include lines 2128a and/or vias 2128b filled with an electrically conductive material such as a metal. The lines 2128a may be arranged to route electrical signals in a direction of a plane that is substantially parallel with a surface of the substrate 2102 upon which the device layer 2104 is formed. For example, the lines 2128a may route electrical signals in a direction in and out of the page from the perspective of FIG. 5. The vias 2128b may be arranged to route electrical signals in a direction of a plane that is substantially perpendicular to the surface of the substrate 2102 upon which the device layer 2104 is formed. In some embodiments, the vias 2128b may electrically couple lines 2128a of different interconnect layers 2106, 2108, and 2110 together.

The interconnect layers 2106, 2108, and 2110 may include an insulator material 2126 disposed between the interconnect structures 2128, as shown in FIG. 5. In some embodiments, the insulator material 2126 disposed between the interconnect structures 2128 in different ones of the interconnect layers 2106, 2108, and 2110 may have different compositions; in other embodiments, the composition of the insulator material 2126 between different interconnect layers 2106, 2108, and 2110 may be the same.

A first interconnect layer 2106 may be formed above the device layer 2104. In some embodiments, the first interconnect layer 2106 may include lines 2128a and/or vias 2128b, as shown. The lines 2128a of the first interconnect layer 2106 may be coupled with contacts (e.g., the S/D contacts 2124) of the device layer 2104.

A second interconnect layer 2108 may be formed above the first interconnect layer 2106. In some embodiments, the second interconnect layer 2108 may include vias 2128b to couple the lines 2128a of the second interconnect layer 2108 with the lines 2128a of the first interconnect layer 2106. Although the lines 2128a and the vias 2128b are structurally delineated with a line within each interconnect layer (e.g., within the second interconnect layer 2108) for the sake of clarity, the lines 2128a and the vias 2128b may be structurally and/or materially contiguous (e.g., simultaneously filled during a dual-damascene process) in some embodiments.

A third interconnect layer 2110 (and additional interconnect layers, as desired) may be formed in succession on the second interconnect layer 2108 according to similar techniques and configurations described in connection with the second interconnect layer 2108 or the first interconnect layer 2106. In some embodiments, the interconnect layers that are “higher up” in the metallization stack 2119 in the IC device 2100 (i.e., farther away from the device layer 2104) may be thicker.

The IC device 2100 may include a solder resist material 2134 (e.g., polyimide or similar material) and one or more conductive contacts 2136 formed on the interconnect layers 2106, 2108, and 2110. In FIG. 5, the conductive contacts 2136 are illustrated as taking the form of bond pads. The conductive contacts 2136 may be electrically coupled with the interconnect structures 2128 and configured to route the electrical signals of the transistor(s) 2140 to other external devices. For example, solder bonds may be formed on the one or more conductive contacts 2136 to mechanically and/or electrically couple a chip including the IC device 2100 with another component (e.g., a circuit board). The IC device 2100 may include additional or alternate structures to route the electrical signals from the interconnect layers 2106, 2108, and 2110; for example, the conductive contacts 2136 may include other analogous features (e.g., posts) that route the electrical signals to external components.

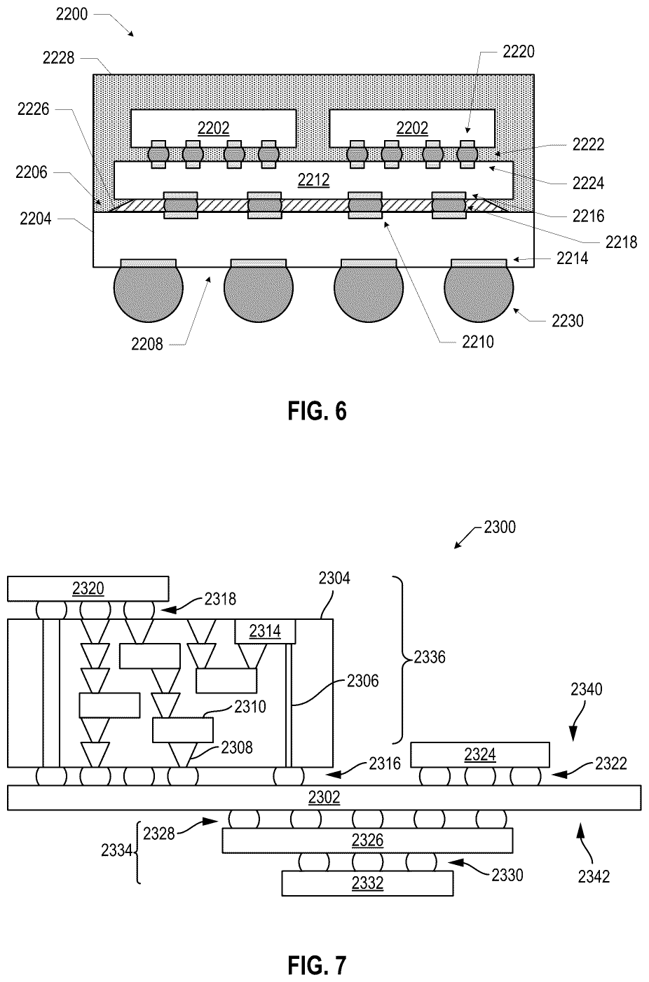

FIG. 6 is a side, cross-sectional view of an example IC package 2200 that may include one or more IC structures with memory cells with semiconductor layers of different doping levels, in accordance with various embodiments. For example, in some embodiments, the dies 2202 may include one or more IC structures with memory cells 102 with semiconductor layers of different doping levels. In another example, in some embodiments, any of the dies 2202 of the IC package 2200 may be implemented as the die 2002 of FIG. 4. In some embodiments, the dies 2202 may include any of the embodiments of the IC device 2100. In embodiments in which the IC package 2200 includes multiple dies 2202, the IC package 2200 may be referred to as a multi-chip package (MCP). The dies 2202 may include circuitry to perform any desired functionality. For example, or more of the dies 2202 may be logic dies (e.g., silicon-based dies), and one or more of the dies 2202 may be memory dies (e.g., high bandwidth memory). In some embodiments, the IC package 2200 may be a system-in-package (SiP). In some embodiments, the IC package 2200 may include a photonics IC (PIC) co-packaged with an IC package. In some embodiments, the IC package 2200 may include fully integrated electronic photonics ICs (EPICs).

The IC package 2200 may include a package substrate 2204 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 2206 and the face 2208, or between different locations on the face 2206, and/or between different locations on the face 2208. These conductive pathways may take the form of any of the interconnect structures 2128 discussed above with reference to FIG. 5.

The package substrate 2204 may include conductive contacts 2210 that are coupled to conductive pathways (not shown) through the package substrate 2204, allowing circuitry within the dies 2202 and/or the interposer 2212 to electrically couple to various ones of the conductive contacts 2214 (or to other devices included in the package substrate 2204, not shown). The IC package 2200 may include an interposer 2212 coupled to the package substrate 2204 via conductive contacts 2216 of the interposer 2212, first-level interconnects 2218, and the conductive contacts 2210 of the package substrate 2204. The first-level interconnects 2218 illustrated in FIG. 6 are solder bumps, but any suitable first-level interconnects 2218 may be used. In some embodiments, no interposer 2212 may be included in the IC package 2200; instead, the dies 2202 may be coupled directly to the conductive contacts 2210 at the face 2206 by first-level interconnects 2218. More generally, one or more dies 2202 may be coupled to the package substrate 2204 via any suitable structure (e.g., a silicon bridge, an organic bridge, one or more waveguides, one or more interposers, wirebonds, etc.).

The IC package 2200 may include one or more dies 2202 coupled to the interposer 2212 via conductive contacts 2220 of the dies 2202, first-level interconnects 2222, and conductive contacts 2224 of the interposer 2212. The conductive contacts 2224 may be coupled to conductive pathways (not shown) through the interposer 2212, allowing circuitry within the dies 2202 to electrically couple to various ones of the conductive contacts 2216 (or to other devices included in the interposer 2212, not shown). The first-level interconnects 2222 illustrated in FIG. 6 are solder bumps, but any suitable first-level interconnects 2222 may be used. For example, the first-level interconnects 2222 may include hybrid bonding interconnects. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

In some embodiments, an underfill material 2226 may be disposed between the package substrate 2204 and the interposer 2212 around the first-level interconnects 2218, and a mold compound 2228 may be disposed around the dies 2202 and the interposer 2212 and in contact with the package substrate 2204. In some embodiments, the underfill material 2226 may be the same as the mold compound 2228. Example materials that may be used for the underfill material 2226 and the mold compound 2228 are epoxy mold materials, as suitable. Second-level interconnects 2230 may be coupled to the conductive contacts 2214. The second-level interconnects 2230 illustrated in FIG. 6 are solder balls (e.g., for a ball grid array arrangement), but any suitable second-level interconnects 2230 may be used (e.g., pins in a pin grid array arrangement or lands in a land grid array arrangement). The second-level interconnects 2230 may be used to couple the IC package 2200 to another component, such as a circuit board (e.g., a motherboard), an interposer, or another IC package, as known in the art and as discussed below with reference to FIG. 7.

Although the IC package 2200 illustrated in FIG. 6 is a flip chip package, other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fanout (FO) package. Although two dies 2202 are illustrated in the IC package 2200 of FIG. 6, an IC package 2200 may include any desired number of dies 2202. An IC package 2200 may include additional passive components, such as surface-mount resistors, capacitors, and inductors disposed on the first face 2206 or the second face 2208 of the package substrate 2204, or on either face of the interposer 2212. More generally, an IC package 2200 may include any other active or passive components known in the art.

FIG. 7 is a side, cross-sectional view of an IC device assembly 2300 that may include one or more IC packages or other electronic components (e.g., a die) including one or more IC structures with memory cells with semiconductor layers of different doping levels in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. Any of the IC packages discussed below with reference to the IC device assembly 2300 may take the form of any of the embodiments of the IC package 2200 discussed above with reference to FIG. 6.

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 7 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (as shown in FIG. 7), male and female portions of a socket, an adhesive, an underfill material, and/or any other suitable electrical and/or mechanical coupling structure.

The package-on-interposer structure 2336 may include an IC package 2320 coupled to an package interposer 2304 by coupling components 2318. The coupling components 2318 may take any suitable form for the application, such as the forms discussed above with reference to the coupling components 2316. Although a single IC package 2320 is shown in FIG. 7, multiple IC packages may be coupled to the package interposer 2304; indeed, additional interposers may be coupled to the package interposer 2304. The package interposer 2304 may provide an intervening substrate used to bridge the circuit board 2302 and the IC package 2320. The IC package 2320 may be or include, for example, a die (the die 2002 of FIG. 4), an IC device (e.g., the IC device 2100 of FIG. 5), or any other suitable component. Generally, the package interposer 2304 may spread a connection to a wider pitch or reroute a connection to a different connection. For example, the package interposer 2304 may couple the IC package 2320 (e.g., a die) to a set of BGA conductive contacts of the coupling components 2316 for coupling to the circuit board 2302. In the embodiment illustrated in FIG. 7, the IC package 2320 and the circuit board 2302 are attached to opposing sides of the package interposer 2304; in other embodiments, the IC package 2320 and the circuit board 2302 may be attached to a same side of the package interposer 2304. In some embodiments, three or more components may be interconnected by way of the package interposer 2304.

In some embodiments, the package interposer 2304 may be formed as a PCB, including multiple metal layers separated from one another by layers of dielectric material and interconnected by electrically conductive vias. In some embodiments, the package interposer 2304 may be formed of an epoxy resin, a fiberglass-reinforced epoxy resin, an epoxy resin with inorganic fillers, a ceramic material, or a polymer material such as polyimide. In some embodiments, the package interposer 2304 may be formed of alternate rigid or flexible materials that may include the same materials described above for use in a semiconductor substrate, such as silicon, germanium, and other group III-V and group IV materials. The package interposer 2304 may include metal lines 2310 and vias 2308, including but not limited to through-silicon vias (TSVs) 2306. The package interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 2304. The package-on-interposer structure 2336 may take the form of any of the package-on-interposer structures known in the art. In some embodiments, the package interposer 2304 may include one or more memory cells 102 with semiconductor layers of different doping levels (e.g., a memory array 100).

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 7 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

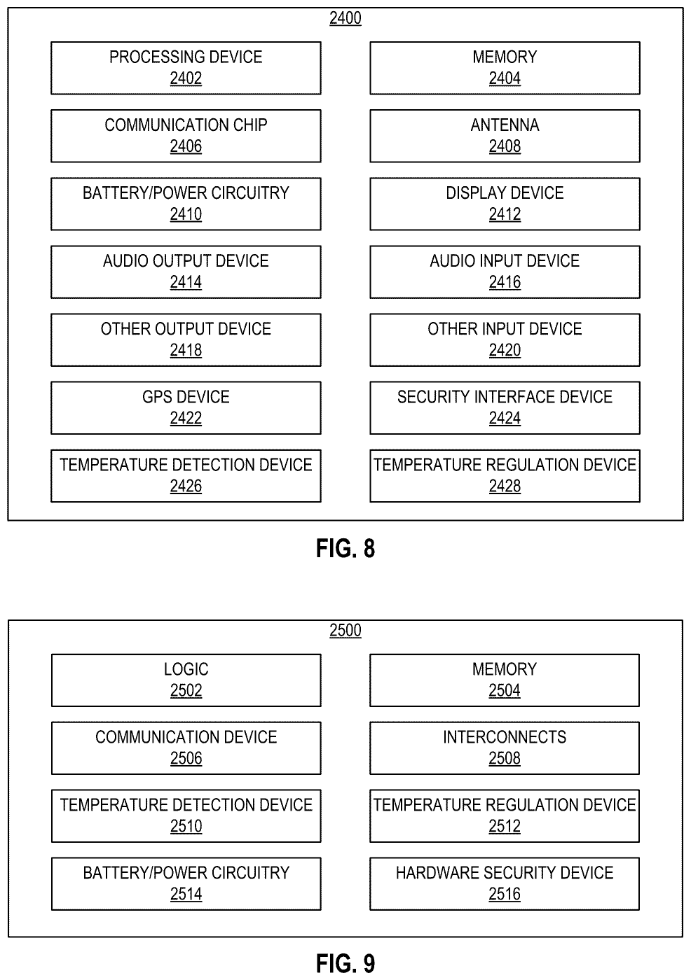

FIG. 8 is a block diagram of an example computing device 2400 that may include one or more components including IC structures with memory cells with semiconductor layers of different doping levels in accordance with any of the embodiments disclosed herein. For example, any suitable ones of the components of the computing device 2400 may include a die (e.g., the die 2002 of FIG. 4) having one or more IC structures with memory cells 102 with semiconductor layers of different doping levels as described herein. Any one or more of the components of the computing device 2400 may include an IC device 2100 of FIG. 5, an IC package 2200 of FIG. 6, or an IC device assembly 2300 of FIG. 7.

A number of components are illustrated in FIG. 8 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 8, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM. In some embodiments, the memory 2404 may include one or more memory cells 102 with semiconductor layers of different doping levels as described herein, e.g., one or more memory arrays 100.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 9 is a block diagram of an example processing device 2500 that may include one or more components including IC structures with memory cells 102 with semiconductor layers of different doping levels as described herein. For example, any suitable ones of the components of the processing device 2500 may include a die (e.g., the die 2002 of FIG. 4) having one or more IC structures with memory cells 102 with semiconductor layers of different doping levels as described herein. Any one or more of the components of the processing device 2500 may include an IC device 2100 of FIG. 5, an IC package 2200 of FIG. 6, or an IC device assembly 2300 of FIG. 7. Any one or more of the components of the processing device 2500 may include, or be included in, a computing device 2400 of FIG. 8; for example, the processing device 2500 may be the processing device 2402 of the computing device 2400.

A number of components are illustrated in FIG. 9 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 9, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 8). In some embodiments, the memory 2504 may be a designated device configured to provide storage functionality for the components of the processing device 2500 (e.g., local), while the memory 2404 may be configured to provide system-level storage functionality for the entire computing device 2400 (e.g., global). In some embodiments, the memory 2504 may include memory that shares a die with the logic circuitry 2502. In some embodiments, the memory 2504 may include one or more memory cells 102 with semiconductor layers of different doping levels as described herein, e.g., one or more memory arrays 100.

The processing device 2500 may include a communication device 2506, which may be implemented substantially as described above with reference to the communication chip 2406 (FIG. 8). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”). In some embodiments, the interconnects 2508 may be implemented as the interconnect structures 2128 of FIG. 5, described above.

The processing device 2500 may include a temperature detection device 2510 which may be implemented substantially as described above with reference to the temperature detection device 2426 of FIG. 8 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 8 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 8. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 8. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

Example 1 provides a memory cell that includes a first semiconductor layer; a second semiconductor layer on (e.g., in direct physical contact with) the first semiconductor layer; a third semiconductor layer on (e.g., in direct physical contact with) the second semiconductor layer; a fourth semiconductor layer on (e.g., in direct physical contact with) the third semiconductor layer; a fifth semiconductor layer on (e.g., in direct physical contact with) the fourth semiconductor layer; and a sixth semiconductor layer on (e.g., in direct physical contact with) the fifth semiconductor layer, where: dopant concentrations of the first semiconductor layer, the fourth semiconductor layer, and the sixth semiconductor layer are higher than dopant concentrations of the second semiconductor layer, the third semiconductor layer, and the fifth semiconductor layer.

Example 2 provides the memory cell according to example 1, where: the first semiconductor layer, the second semiconductor layer, and the fourth semiconductor layer have a first conductivity type, and the fourth semiconductor layer and the sixth semiconductor layer have a second conductivity type opposite to the first conductivity type.

Example 3 provides the memory cell according to example 2, where the first conductivity type is an N-type and the second conductivity type is a P-type.

Example 4 provides the memory cell according to example 2, where the first conductivity type is a P-type and the second conductivity type is an N-type.

Example 5 provides the memory cell according to any one of examples 1-4, where the dopant concentrations of the first semiconductor layer, the fourth semiconductor layer, and the sixth semiconductor layer are at least 10¹⁸ dopants per cubic centimeter.

Example 6 provides the memory cell according to any one of examples 1-5, where the dopant concentrations of the second semiconductor layer, the third semiconductor layer, and the fifth semiconductor layer are below 10¹⁸ dopants per cubic centimeter.

Example 7 provides the memory cell according to any one of examples 1-6, where the dopant concentration of the fifth semiconductor layer is below 10¹⁵ dopants per cubic centimeter.

Example 8 provides the memory cell according to any one of examples 1-7, where a thickness of the third semiconductor layer is larger than a thickness of the first semiconductor layer by a factor between 2 and 100.

Example 9 provides the memory cell according to example 8, where the thickness of the third semiconductor layer is larger than a thickness of the second semiconductor layer, and the thickness of the second semiconductor layer is larger than the thickness of the first semiconductor layer.

Example 10 provides the memory cell according to examples 8 or 9, where a thickness of the fifth semiconductor layer is less than half of the thickness of the first semiconductor layer.

Example 11 provides the memory cell according to any one of examples 8-10, where a thickness of the fourth semiconductor layer is about same as the thickness of the first semiconductor layer.

Example 12 provides the memory cell according to any one of examples 8-11, where a thickness of the sixth semiconductor layer is about same as the thickness of the first semiconductor layer.

Example 13 provides the memory cell according to any one of examples 8-12, where the thickness of the first semiconductor layer is between about 3 nanometers and about 100 nanometers, e.g., between about 5 nanometers and about 25 nanometers, or between about 3 nanometers and 10 nanometers.

Example 14 provides a memory cell that includes a first semiconductor layer; a second semiconductor layer on (e.g., in direct physical contact with) the first semiconductor layer; a third semiconductor layer on (e.g., in direct physical contact with) the second semiconductor layer; a fourth semiconductor layer on (e.g., in direct physical contact with) the third semiconductor layer; a fifth semiconductor layer on (e.g., in direct physical contact with) the fourth semiconductor layer; and a sixth semiconductor layer on (e.g., in direct physical contact with) the fifth semiconductor layer, where: the first semiconductor layer, the second semiconductor layer, and the fourth semiconductor layer have a first conductivity type, and the fourth semiconductor layer and the sixth semiconductor layer have a second conductivity type opposite to the first conductivity type.

Example 15 provides the memory cell according to example 14, where: dopant concentrations of the first semiconductor layer, the fourth semiconductor layer, and the sixth semiconductor layer are at least 10¹⁸ dopants per cubic centimeter, dopant concentrations of the second semiconductor layer and the third semiconductor layer are below 10¹⁸ dopants per cubic centimeter, and a dopant concentration of the fifth semiconductor layer is below 10¹⁵ dopants per cubic centimeter.

Example 16 provides the memory cell according to example 15, where the dopant concentrations of the second semiconductor layer and the third semiconductor layer are higher than the dopant concentration of the fifth semiconductor layer.

Example 17 provides the memory cell according to any one of examples 14-16, where: a thickness of the third semiconductor layer is larger than a thickness of the first semiconductor layer by a factor between 2 and 100, and a thickness of the fifth semiconductor layer is less than half of the thickness of the first semiconductor layer.

Example 18 provides the memory cell according to example 17, where: the thickness of the third semiconductor layer is larger than a thickness of the second semiconductor layer, the thickness of the second semiconductor layer is larger than the thickness of the first semiconductor layer, a thickness of the fourth semiconductor layer is about same as the thickness of the first semiconductor layer, and a thickness of the sixth semiconductor layer is about same as the thickness of the first semiconductor layer.

Example 19 provides an IC structure that includes a first control line extending along a first direction in a first plane; a second control line extending along a second direction in a second plane, where the second direction is perpendicular to the first direction and the second plane is parallel to the first plane; and a memory cell connected to the first control line and the second control line, where the memory cell includes a first semiconductor layer, a second semiconductor layer on (e.g., in direct physical contact with) the first semiconductor layer, a third semiconductor layer on (e.g., in direct physical contact with) the second semiconductor layer, a fourth semiconductor layer on (e.g., in direct physical contact with) the third semiconductor layer, a fifth semiconductor layer on (e.g., in direct physical contact with) the fourth semiconductor layer, and a sixth semiconductor layer on (e.g., in direct physical contact with) the fifth semiconductor layer, where: dopant concentrations of the first semiconductor layer, the fourth semiconductor layer, and the sixth semiconductor layer are at least 10¹⁸ dopants per cubic centimeter, dopant concentrations of the second semiconductor layer and the third semiconductor layer are below 10¹⁸ dopants per cubic centimeter, and a dopant concentration of the fifth semiconductor layer is below 10¹⁵ dopants per cubic centimeter.

Example 20 provides the IC structure according to example 19, where: the first semiconductor layer, the second semiconductor layer, and the fourth semiconductor layer have a first conductivity type, and the fourth semiconductor layer and the sixth semiconductor layer have a second conductivity type opposite to the first conductivity type.

Example 21 provides an IC package that includes an IC die, including a memory cell or an IC structure according to any one of the preceding examples; and a further component, coupled to the IC die.

Example 22 provides the IC package according to example 21, where the further component is one of a package substrate, an interposer, or a further IC die.

Example 23 provides the IC package according to examples 21 or 22, further including an insulator material around at least a portion of the IC die.

Example 24 provides the IC package according to any one of examples 21-23, further including interconnects between the further component and the IC die.

Example 25 provides the IC package according to example 24, where the interconnects are solder bumps.

Example 26 provides the IC package according to example 24, where the interconnects are hybrid bonding interconnects.

Example 27 provides the IC package according to any one of examples 24-26, further including first conductive contacts at a surface of the further component closest to the IC die; and second conductive contacts at a surface of the IC die closest to the further component, where the interconnects are between the first conductive contacts and the second conductive contacts.

Example 28 provides the IC package according to example 27, where at least one of the first conductive contacts or the second conductive contacts includes a conductive pad.

Example 29 provides the IC package according to example 27, where at least one of the first conductive contacts or the second conductive contacts includes a conductive socket.

Example 30 provides the IC package according to any one of examples 21-29, where: the further component is an interposer, the IC package further includes a package substrate coupled to the interposer, the IC die is coupled to a first face of the interposer, and the package substrate is coupled to a second face of the interposer opposite the first face of the interposer.

Example 31 provides the IC package according to example 30, further including interconnects between the interposer and the package substrate.

Example 32 provides the IC package according to example 31, further including an underfill material around the interconnects.

Example 33 provides an electronic device that includes a carrier substrate; and one or more of the IC structures or memory cells according to any one of the preceding examples and/or the IC package according to any one of the preceding claims, coupled to the carrier substrate.

Example 34 provides the electronic device according to example 33, where the carrier substrate is a motherboard.

Example 35 provides the electronic device according to example 33, where the carrier substrate is a PCB.

Example 36 provides the electronic device according to any one of examples 33-35, where the electronic device is a wearable electronic device (e.g., a smart watch) or handheld electronic device (e.g., a mobile phone).

Example 37 provides the electronic device according to any one of examples 33-36, where the electronic device further includes one or more communication chips and an antenna.

Example 38 provides the electronic device according to any one of examples 33-37, where the electronic device is memory device.

Example 39 provides the electronic device according to any one of examples 33-37, where the electronic device is one of a radio frequency (RF) transceiver, a switch, a power amplifier, a low-noise amplifier, a filter, a filter bank, a duplexer, an upconverter, or a downconverter of an RF communications device, e.g., of an RF transceiver.

Example 40 provides the electronic device according to any one of examples 33-37, where the electronic device is a computing device.

Example 41 provides the electronic device according to any one of examples 33-40, where the electronic device is included in a base station of a wireless communication system.

Example 42 provides the electronic device according to any one of examples 33-40, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A memory cell, comprising:
a first semiconductor layer;
a second semiconductor layer on the first semiconductor layer;
a third semiconductor layer on the second semiconductor layer;
a fourth semiconductor layer on the third semiconductor layer;
a fifth semiconductor layer on the fourth semiconductor layer; and
a sixth semiconductor layer on the fifth semiconductor layer,
wherein:
dopant concentrations of the first semiconductor layer, the fourth semiconductor layer, and the sixth semiconductor layer are higher than dopant concentrations of the second semiconductor layer, the third semiconductor layer, and the fifth semiconductor layer.

2. The memory cell according to claim 1, wherein:
the first semiconductor layer, the second semiconductor layer, and the fourth semiconductor layer have a first conductivity type, and
the fourth semiconductor layer and the sixth semiconductor layer have a second conductivity type opposite to the first conductivity type.

3. The memory cell according to claim 2, wherein the first conductivity type is an N-type, and the second conductivity type is a P-type.

4. The memory cell according to claim 2, wherein the first conductivity type is a P-type, and the second conductivity type is an N-type.

5. The memory cell according to claim 1, wherein the dopant concentrations of the first semiconductor layer, the fourth semiconductor layer, and the sixth semiconductor layer are at least 10¹⁸ dopants per cubic centimeter.

6. The memory cell according to claim 1, wherein the dopant concentrations of the second semiconductor layer, the third semiconductor layer, and the fifth semiconductor layer are below 10¹⁸ dopants per cubic centimeter.

7. The memory cell according to claim 1, wherein the dopant concentration of the fifth semiconductor layer is below 10¹⁵ dopants per cubic centimeter.

8. The memory cell according to claim 1, wherein a thickness of the third semiconductor layer is larger than a thickness of the first semiconductor layer by a factor between 2 and 100.

9. The memory cell according to claim 8, wherein the thickness of the third semiconductor layer is larger than a thickness of the second semiconductor layer, and the thickness of the second semiconductor layer is larger than the thickness of the first semiconductor layer.

10. The memory cell according to claim 8, wherein a thickness of the fifth semiconductor layer is less than half of the thickness of the first semiconductor layer.

11. The memory cell according to claim 8, wherein a thickness of the fourth semiconductor layer is about same as the thickness of the first semiconductor layer.

12. The memory cell according to claim 8, wherein a thickness of the sixth semiconductor layer is about same as the thickness of the first semiconductor layer.

13. The memory cell according to claim 8, wherein the thickness of the first semiconductor layer is between about 3 nanometers and about 100 nanometers.

14. A memory cell, comprising:
a first semiconductor layer;
a second semiconductor layer in contact with the first semiconductor layer;
a third semiconductor layer in contact with the second semiconductor layer;
a fourth semiconductor layer in contact with the third semiconductor layer;
a fifth semiconductor layer in contact with the fourth semiconductor layer; and
a sixth semiconductor layer in contact with the fifth semiconductor layer,
wherein:
the first semiconductor layer, the second semiconductor layer, and the fourth semiconductor layer have a first conductivity type, and
the fourth semiconductor layer and the sixth semiconductor layer have a second conductivity type opposite to the first conductivity type.

15. The memory cell according to claim 14, wherein:
dopant concentrations of the first semiconductor layer, the fourth semiconductor layer, and the sixth semiconductor layer are at least 10¹⁸ dopants per cubic centimeter,
dopant concentrations of the second semiconductor layer and the third semiconductor layer are below 10¹⁸ dopants per cubic centimeter, and
a dopant concentration of the fifth semiconductor layer is below 10¹⁵ dopants per cubic centimeter.

16. The memory cell according to claim 15, wherein the dopant concentrations of the second semiconductor layer and the third semiconductor layer are higher than the dopant concentration of the fifth semiconductor layer.

17. The memory cell according to claim 14, wherein:
a thickness of the third semiconductor layer is larger than a thickness of the first semiconductor layer by a factor between 2 and 100, and
a thickness of the fifth semiconductor layer is less than half of the thickness of the first semiconductor layer.

18. The memory cell according to claim 17, wherein:
the thickness of the third semiconductor layer is larger than a thickness of the second semiconductor layer,
the thickness of the second semiconductor layer is larger than the thickness of the first semiconductor layer,
a thickness of the fourth semiconductor layer is about same as the thickness of the first semiconductor layer, and
a thickness of the sixth semiconductor layer is about same as the thickness of the first semiconductor layer.

19. An integrated circuit (IC) structure comprising:
a first control line extending along a first direction in a first plane;
a second control line extending along a second direction in a second plane, wherein the second direction is perpendicular to the first direction and the second plane is parallel to the first plane; and
a memory cell connected to the first control line and the second control line, wherein the memory cell includes a first semiconductor layer, a second semiconductor layer over the first semiconductor layer, a third semiconductor layer over the second semiconductor layer, a fourth semiconductor layer over the third semiconductor layer, a fifth semiconductor layer over the fourth semiconductor layer, and a sixth semiconductor layer over the fifth semiconductor layer,
wherein:
dopant concentrations of the first semiconductor layer, the fourth semiconductor layer, and the sixth semiconductor layer are at least 10¹⁸ dopants per cubic centimeter,
dopant concentrations of the second semiconductor layer and the third semiconductor layer are below 10¹⁸ dopants per cubic centimeter, and
a dopant concentration of the fifth semiconductor layer is below 10¹⁵ dopants per cubic centimeter.

20. The IC structure according to claim 19, wherein:
the first semiconductor layer, the second semiconductor layer, and the fourth semiconductor layer have a first conductivity type, and
the fourth semiconductor layer and the sixth semiconductor layer have a second conductivity type opposite to the first conductivity type.
